(19) United States
(12) Patent Application Publication
(10) Pub. No.: US 2026/0301649 A1
(43) Pub. Date: Oct. 1, 2026

(54) TILING DISPLAY DEVICE

(71) Applicant: LG Display Co., Ltd., Seoul (KR)

(72) Inventor: Daehyun Seo, Goyang-si (KR)

(21) Appl. No.: 19/406,962

(22) Filed: Dec. 3, 2025

(30) Foreign Application Priority Data
Mar. 31, 2025 (KR) 10-2025-0040894

(51) Int. Cl. G09G 3/32

(52) U.S. Cl. CPC G09G 3/32; G09G 2300/026; G09G 2310/0267; G09G 2330/045

(57) ABSTRACT

A tiling display device including a first display device and a second display device. Each of the first display device and the second display device includes a substrate including an active area and a non-active area surrounding the active area, a plurality of light emitting elements disposed in each of the plurality of sub-pixels on the substrate, a printed circuit board disposed on one side of the substrate on a rear surface of the substrate and electrically connected to the plurality of light emitting elements, and a gate driver configured to transmit a scan signal to the plurality of sub-pixels. The gate driver transmits the scan signal from a sub-pixel disposed on the other side opposite to one side of the substrate, among the plurality of sub-pixels, to a sub-pixel disposed on one side of the substrate.

### CROSS REFERENCE TO RELATED APPLICATION

This application claims priority from and the benefit of Korean Patent Application No. 10-2025-0040894, filed on March 31, 2025, which is hereby incorporated by reference for all purposes as if fully set forth herein.

### BACKGROUND

### FIELD

Embodiments of the invention relate generally to a tiling display device having improved display quality.

### DISCUSSION OF THE BACKGROUND

Display devices are applied to various electronic devices, such as TVs, mobile phones, laptops, and tablets.

Display devices include an organic light emitting display (OLED) device that emits light by itself, and a liquid crystal display (LCD) device that requires a separate light source.

Recently, a display device including a light emitting diode (LED) has attracted attention as a next-generation display device. Since the light emitting element is formed of an inorganic material rather than an organic material, the light emitting element has a higher lighting speed than the LCD device or the OLED device, has excellent luminous efficiency, and can display an image having a high luminance.

The above information disclosed in this Background section is only for understanding of the background of the inventive concepts, and, therefore, it may contain information that does not constitute prior art.

### SUMMARY

Tiling display devices according to embodiments of the invention are capable of minimizing a driving deviation between display devices and having improved display quality.

Additional features of the inventive concepts will be set forth in the description which follows, and in part will be apparent from the description, or may be learned by practice of the inventive concepts.

According to one or more embodiments of the invention, a tiling display device includes a plurality of display devices, including a first display device and a second display device. Each of the first display device and the second display device includes: a substrate including an active area in which a plurality of sub-pixels are defined and a non-active area surrounding the active area; a plurality of light emitting elements disposed in each of the plurality of sub-pixels on the substrate; a printed circuit board disposed on one side of the substrate on a rear surface of the substrate and electrically connected to the plurality of light emitting elements; and a gate driver configured to transmit a scan signal to the plurality of sub-pixels. The gate driver is configured to transmit the scan signal from a sub-pixel disposed on the other side opposite to one side of the substrate, among the plurality of sub-pixels, to a sub-pixel disposed on one side of the substrate.

The first display device and the second display device are tiled so that one side of the substrate of the first display device and one side of the substrate of the second display device face each other.

The plurality of sub-pixels may include a plurality of first sub-pixels, a plurality of second sub-pixels, and a plurality of third sub-pixels emitting light of different colors. The plurality of first sub-pixels, the plurality of second sub-pixels, and the plurality of third sub-pixels may be continuously disposed along the first direction. The plurality of first sub-pixels, the plurality of second sub-pixels, and the plurality of third sub-pixels may be alternately disposed along the second direction.

In a state in which the first display device and the second display device are tiled, the plurality of first sub-pixels of the first display device and the plurality of third sub-pixels of the second display device may be continuously disposed along the first direction, and the plurality of third sub-pixels of the first display device and the plurality of first sub-pixels of the second display device may be continuously disposed along the first direction.

In a state in which the first display device and the second display device are tiled, the plurality of first sub-pixels of the first display device may be alternately disposed with the plurality of first sub-pixels of the second display device, and the plurality of third sub-pixels of the first display device may be alternately disposed with the plurality of third sub-pixels of the second display device.

In a state in which the first display device and the second display device are tiled, the plurality of second sub-pixels of the first display device and the plurality of second sub-pixels of the second display device may be continuously disposed along the first direction.

The plurality of sub-pixels may include a plurality of first sub-pixels, a plurality of second sub-pixels, and a plurality of third sub-pixels emitting light of different colors. The plurality of first sub-pixels and the plurality of third sub-pixels may be alternately disposed along the first direction, the plurality of second sub-pixels may be continuously disposed along the first

direction. The plurality of first sub-pixels, the plurality of second sub-pixels, and the plurality of third sub-pixels may be alternately disposed along the second direction.

In a state in which the first display device and the second display device are tiled, the plurality of first sub-pixels and the plurality of third sub-pixels may be alternately disposed along the first direction in the first display device and the second display device.

In a state in which the first display device and the second display device are tiled, the plurality of second sub-pixels of the first display device and the plurality of second sub-pixels of the second display device may be continuously disposed along the first direction.

According to yet another embodiment of the invention, a tiling display device includes a plurality of display devices that are tiled. Each of the display devices includes: a substrate including an active area in which a plurality of sub-pixels is defined and a non-active area surrounding the active area; a plurality of sub-pixels disposed along first to m-th rows and first to n-th columns, wherein m, n is a natural number of 2 or more; a plurality of light emitting elements disposed in each of the plurality of sub-pixels; and a printed circuit board disposed on one side of the substrate along a row direction on a rear surface of the substrate and electrically connected to the plurality of light emitting elements. The printed circuit board is disposed to be adjacent to sub-pixels disposed in a first row among the first row to the m-th row. A sub-pixel disposed in the first row among the plurality of sub-pixels is disposed to face a sub-pixel disposed in the first row of the plurality of display devices adjacent in the column direction.

Each of the plurality of display devices further may include a gate driver configured to transmit a scan signal to the plurality of sub-pixels, and the gate driver may be configured to transmit the scan signal from a sub-pixel disposed in the m-th row to a sub-pixel disposed in the first row among the plurality of sub-pixels.

The plurality of display devices adjacent to each other in the column direction may be disposed so that the printed circuit boards disposed in each of the plurality of display devices face each other.

The plurality of sub-pixels may include a plurality of first sub-pixels, a plurality of second sub-pixels, and a plurality of third sub-pixels emitting light of different colors. In each of the plurality of display devices, the plurality of first sub-pixels, the plurality of second sub-pixels, and the plurality of third sub-pixels are respectively continuously disposed along the column direction, and the plurality of first sub-pixels, the plurality of second sub-pixels, and the plurality of third sub-pixels are alternately disposed along the row direction.

The plurality of first sub-pixels of the plurality of display devices may be disposed in the same column as the plurality of third sub-pixels of the display device adjacent to the plurality of display devices in the column direction. The plurality of third sub-pixels of the plurality of display devices may be disposed in the same column as the plurality of first sub-pixels of the display device adjacent to the plurality of display devices in the column direction.

The plurality of second sub-pixels of the plurality of display devices may be disposed in the same column as the plurality of second sub-pixels of the display device adjacent to the plurality of display devices in the column direction.

The plurality of sub-pixels may include a plurality of first sub-pixels, a plurality of second sub-pixels, and a plurality of third sub-pixels emitting light of different colors. In each of the plurality of display devices, the plurality of first sub-pixels and the plurality of third sub-pixels may be alternately disposed along the column direction, the plurality of second sub-pixels may be continuously disposed along the column direction, and the plurality of first sub-pixels, the plurality of second sub-pixels, and the plurality of third sub-pixels may be alternately disposed along the row direction.

The plurality of first sub-pixels of the plurality of display devices may be disposed in the same column as the plurality of first sub-pixels of the display device adjacent to the plurality of display devices in the column direction, and the plurality of third sub-pixels of the plurality of display devices are disposed in the same column as the plurality of third sub-pixels of the display device adjacent to the plurality of display devices in the column direction.

The plurality of second sub-pixels of the plurality of display devices may be disposed in the same column as the plurality of second sub-pixels of the display device adjacent to the plurality of display devices in the column direction.

According to yet another embodiment of the invention, a tiling display device includes a first display device and a second display device arranged adjacent to each other in a first direction. One side of the first display device faces one side of the second display device. Each of the first display device and the second display device includes: a substrate including an active area in which a plurality of sub-pixels is defined and a non-active area surrounding the active area; a plurality of light emitting elements respectively disposed in the plurality of sub-pixels; a printed circuit board disposed on a rear surface of the substrate at the one side of the substrate and electrically connected to the plurality of light emitting elements; and a gate driver configured to apply a scan signal to the plurality of sub-pixels by row from the other side opposite to the one side toward the one side.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic configuration diagram of a display device constituting a tiling display device according to an embodiment of the invention.

FIG. 2A is a partial cross-sectional view of a display device constituting a tiling display device according to an exemplary embodiment of the invention.

FIG. 2B is a perspective view of a tiling display device according to an embodiment of the invention.

FIG. 3 is a plan view of a tiling display device according to an embodiment of the invention.

FIG. 4 is a rear plan view of a tiling display device according to an embodiment of the invention.

FIG. 5 is a diagram for explaining an order of applying a scan signal to a tiling display device according to an embodiment of the invention.

FIG. 6 is a plan view of a tiling display device according to another embodiment of the invention.

FIG. 7 is a rear plan view of a tiling display device according to another embodiment of the invention.

FIG. 8 is a diagram for explaining an order of applying a scan signal to a tiling display device according to another embodiment of the invention.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As is customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

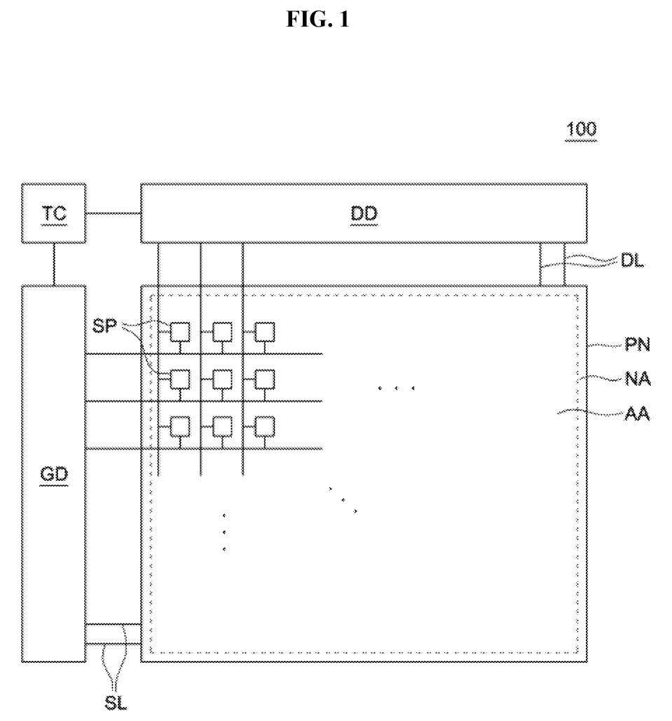

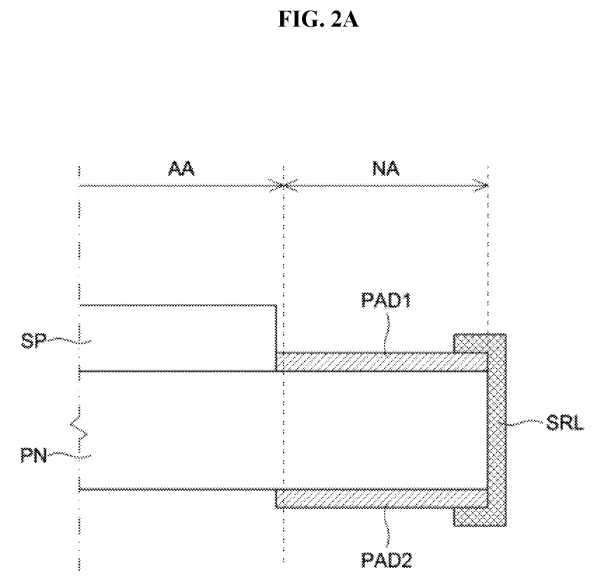

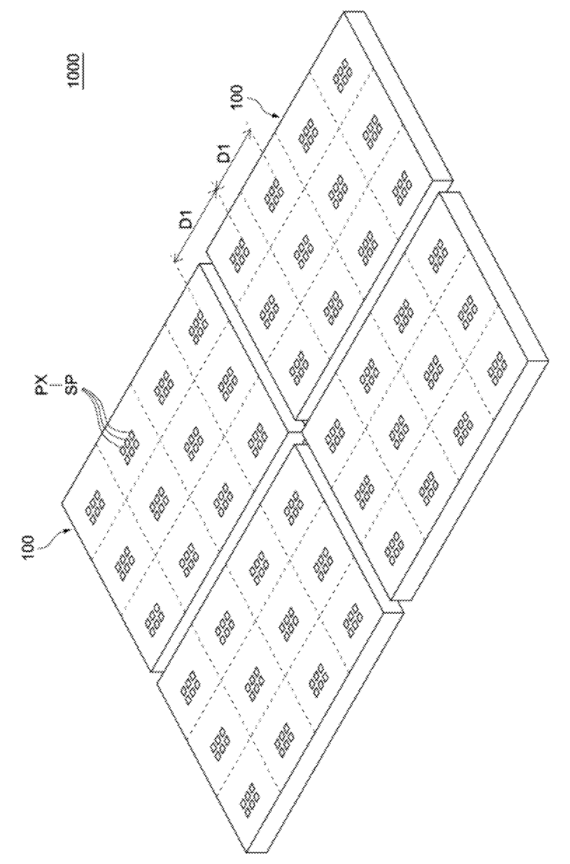

FIG. 1 is a schematic configuration diagram of a display device constituting a tiling display device according to an embodiment of the invention. FIG. 2A is a partial cross-sectional view of a display device constituting a tiling display device according to an embodiment of the invention. FIG. 2B is a perspective view of a tiling display device according to an embodiment of the invention. In FIG. 1, for the convenience of description, among various components of the display device 100, only a display panel PN, a gate driver GD, a data driver DD, and a timing controller TC are illustrated.

Referring to FIG. 1, a display device 100 includes a display panel PN including a plurality of sub-pixels SP, a gate driver GD, and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals provided from the timing controller TC. FIG. 1 illustrates that one gate driver GD is disposed to be spaced apart from one side of the display panel PN. However, the number and arrangement of the gate drivers GD are not limited thereto.

The data driver DD converts image data input from the timing controller TC into a data voltage using a reference gamma voltage according to a plurality of data control signals provided from the timing controller TC. The data driver DD may supply the converted data voltage to a plurality of data lines DL.

The timing controller TC aligns image data input from the outside and supplies the image data to the data driver DD. The timing controller TC may generate a gate control signal and a data control signal by using a synchronization signal input from the outside, for example, a dot clock signal, a data enable signal, and a horizontal/vertical synchronization signal. Further, the timing controller TC supplies the generated gate control signal and data control signal to the gate driver GD and the data driver DD, respectively, to control the gate driver GD and the data driver DD.

The display panel PN is configured to display images to a user and includes a plurality of sub-pixels SP. In the display panel PN, the plurality of scan lines SL and the plurality of data lines DL intersect each other, and each of the plurality of sub-pixels SP is connected to the scan line SL and the data line DL. In addition, although not illustrated in the drawings, each of the plurality of sub-pixels SP may be connected to a high potential power line, a low potential power line, a reference line, and the like.

In the display panel PN, an active area AA and a non-active area NA around the active area AA may be defined. In some embodiments, the non-active area NA may enclose the active area AA.

The active area AA is an area in which images are displayed in the display device 100. In the active area AA, a plurality of sub-pixels SP constituting a plurality of pixels PX and a circuit for driving the plurality of sub-pixels SP may be disposed. The plurality of sub-pixels SP is a minimum unit constituting the active area AA, and ‘n’ sub-pixels SP may form one pixel, in which n is a natural number. In each of the plurality of sub-pixels SP, a light emitting element, a thin film transistor for driving the light emitting element, and the like may be disposed. The plurality of light emitting elements may be differently defined depending on the type of the display panel PN. For example, when the display panel PN is an inorganic light emitting display panel, the light emitting element may be a light emitting diode (LED) or a micro light emitting diode (mLED).

In the active area AA, a plurality of signal lines for transmitting various signals to the plurality of sub-pixels SP are disposed. For example, the plurality of signal lines may include a plurality of data lines DL which supply a data voltage to each of the plurality of sub-pixels SP, a plurality of scan lines SL which supply a gate voltage to each of the plurality of sub-pixels SP, and the like. The plurality of scan lines SL may extend in one direction in the active area AA and be electrically connected to the plurality of sub-pixels SP, and the plurality of data lines DL may extend in a direction different from the one direction in the active area AA and be electrically connected to the plurality of sub-pixels SP. In addition, in the active area AA, a low potential power line, a high potential power line, and the like may be further disposed, but are not limited thereto.

The non-active area NA is an area where no image is displayed, and in the non-active area NA, a link line and a pad for transmitting a signal to the sub-pixel SP of the active area AA, or a driving IC such as a gate driver IC and a data driver IC may be disposed.

A driver, such as a gate driver GD, a data driver DD, and a timing controller TC, may be electrically connected to the display panel PN in various ways. For example, the gate driver GD may be mounted in the non-active area NA in a gate-in-panel (GIP) manner or mounted between the plurality of sub-pixels SP in the active area AA in a gate-in-active area (GIA) manner. For example, the data driver DD and the timing controller TC may be formed in separate flexible printed circuit FPC and printed circuit board PCB and may be electrically connected to the display panel PN by bonding the flexible printed circuit and the printed circuit board to the pad formed in the non-active area NA of the display panel PN. When the gate driver GD is mounted in the GIP manner, and the data driver DD and the timing controller TC transmit signals to the display panel PN through the pad of the non-active area NA, it becomes necessary to secure the area of the non-active area NA to accommodate the gate driver GD and the pad, which may lead to an increase in the width of the bezel.

In contrast, when the gate driver GD is mounted in the active area AA in the GIA manner and a side line SRL, which connects the signal line on the front surface of the display panel PN to the pad on the rear surface of the display panel PN, is formed to bond the flexible printed circuit FPC and the printed circuit board PCB to the rear surface of the display panel PN, the non-active area NA on the front surface of the display panel PN may be minimized. In this manner, when the gate driver GD, the data driver DD, and the timing controller TC are connected to the display panel PN as described above, a zero bezel with substantially no bezel may be achieved.

More particularly, referring to FIGS. 2A and 2B, a plurality of pads for transmitting various signals to the plurality of sub-pixels SP is disposed in the non-active area NA of the display panel PN. For example, a first pad PAD1 for transmitting a signal to the plurality of sub-pixels SP is disposed in the non-active area NA on the front surface of the display panel PN, and a second pad PAD2 electrically connected to a driving component, such as a flexible printed circuit FPC and a printed circuit board PCB, is disposed in the non-active area NA on the rear surface of the display panel PN. Accordingly, only a minimal pad area in which the first pad PAD1 of the non-active area NA is disposed may be formed on the front surface of the display panel PN on which an image is displayed.

In this case, although not illustrated in the drawings, various signal lines connected to the plurality of sub-pixels SP, for example, a scan line SL or a data line DL, extend from the active area AA to the non-active area NA to be electrically connected to the first pad PAD1.

Further, the side line SRL is disposed along the side surface of the display panel PN. The side line SRL may electrically connect the first pad PAD1 on the front surface of the display panel PN and the second pad PAD2 on the rear surface of the display panel PN. Therefore, a signal from the driving component on the rear surface of the display panel PN may be transmitted to the plurality of sub-pixels SP through the second pad PAD2, the side line SRL, and the first pad PAD1. Accordingly, a signal transmission path is formed from the front surface to the side surface and the rear surface of the display panel PN to minimize the area of the non-active area NA on the front surface of the display panel PN.

Further, referring to FIG. 2B, a tiling display device having a large screen may be implemented by connecting a plurality of display devices 100. In this case, when the tiling display device 1000 is implemented using the display device 100 with a minimized bezel as illustrated in FIG. 2A, a seam area in which an image between the display device 100 and the display device 100 is not displayed is minimized to improve the display quality.

For example, the plurality of sub-pixels SP may form one pixel PX, and an interval D1 between an outermost pixel PX of one display device 100 and an outermost pixel PX of another display device 100 adjacent to one display device 100 may be implemented to be equal to an interval D1 between pixels in one display device 100. Accordingly, the distance D1 between pixels between adjacent display devices 100 may be constantly configured to minimize the seam area.

However, FIGS. 2A and 2B are illustrative so that the display device 100 constituting the tiling display device 1000 according to an exemplary embodiment of the invention may be a general display device 100 having a bezel, but is not limited thereto.

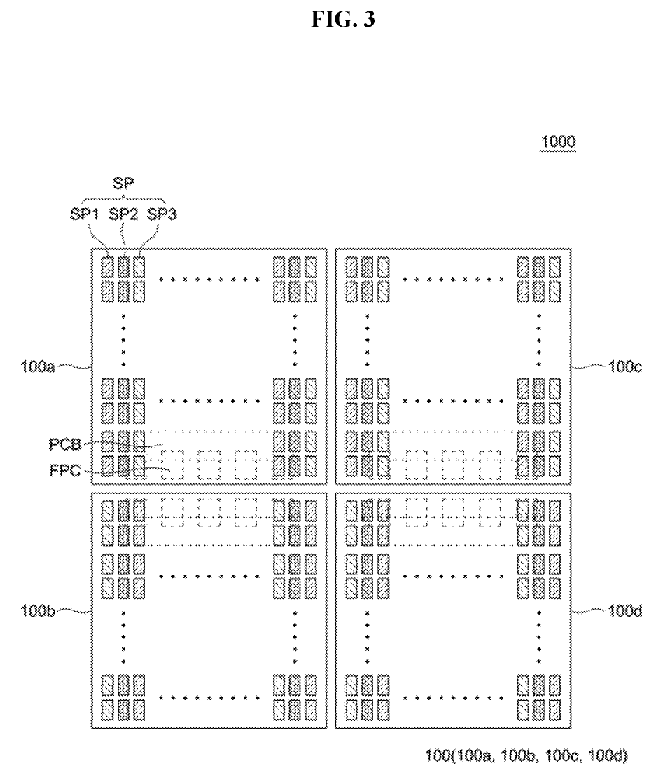

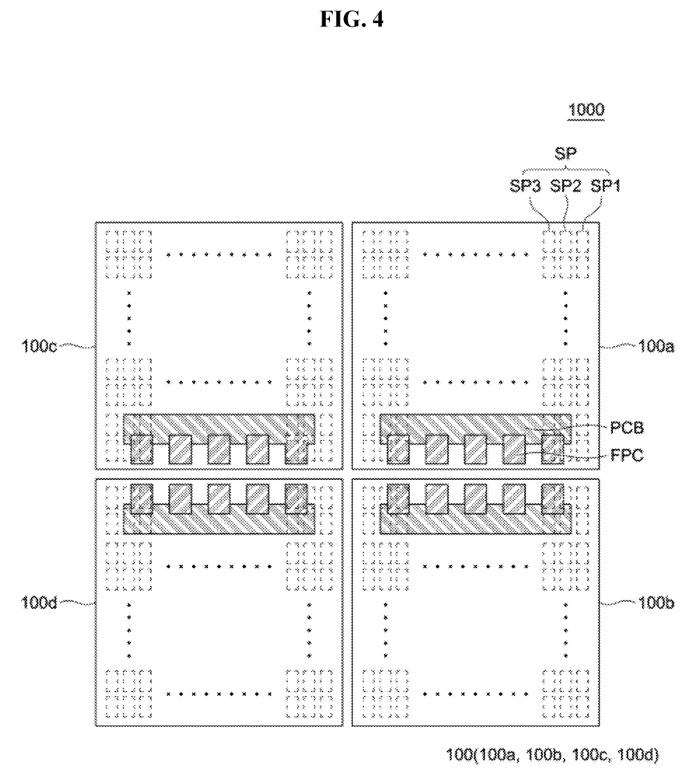

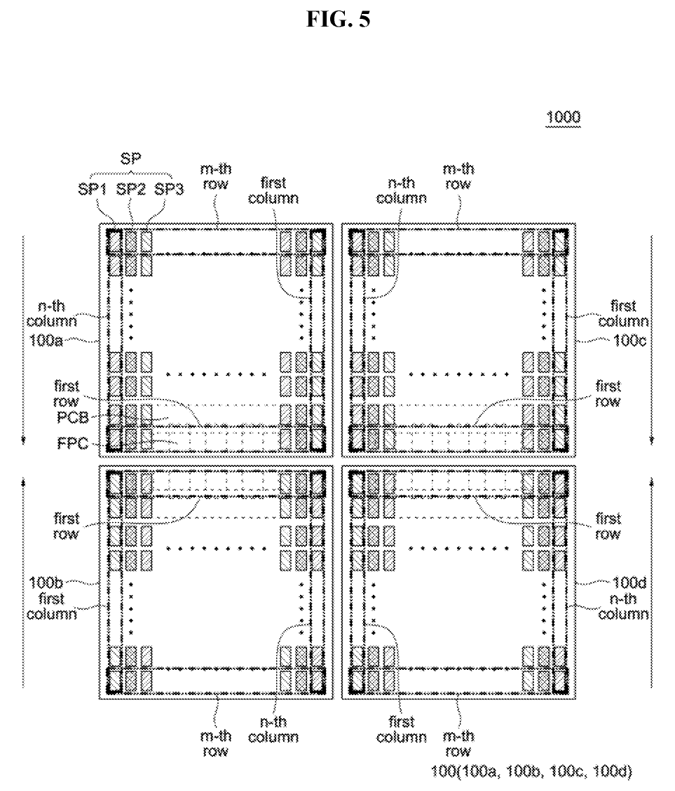

FIG. 3 is a plan view of a tiling display device according to an embodiment of the invention. FIG. 4 is a rear plan view of a tiling display device according to an embodiment of the invention. FIG. 5 is a diagram for explaining an order of applying a scan signal to a tiling display device according to an embodiment of the invention. An arrow in FIG. 5 indicates a scan signal application direction.

First, referring to FIGS. 2B and 3, a plurality of display devices 100 arranged along a first direction, for example, a column direction and a second direction, for example, a row direction, are tiled to implement a tiling display device 1000.

For example, referring to FIGS. 3 to 5, the plurality of display devices 100 may include a first display device 100a, a second display device 100b, a third display device 100c, and a fourth display device 100d having the same arrangement structure as the sub-pixel SP. For example, the first display device 100a may be disposed in the same column as the second display device 100b, and the third display device 100c may be disposed in the same column as the fourth display device 100d. The first display device 100a may be disposed in the same row as the third display device 100c, and the second display device 100b may be disposed in the same row as the fourth display device 100d. In this way, the first display device 100a, the second display device 100b, the third display device 100c, and the fourth display device 100d are repeatedly arranged to implement the tiling display device 1000, but it is not limited thereto.

Each of the plurality of display devices 100 may include a substrate. The substrate is a component for supporting various components included in a plurality of display devices and may be made of an insulating material. For example, the substrate may be made of glass or resin. In addition, the substrate may include polymer or plastic, or may be made of a material having flexibility, but is not limited thereto.

A plurality of sub-pixels SP may be defined on the substrate. Each of the plurality of sub-pixels SP includes a light emitting element and a pixel circuit to independently emit light. For example, the plurality of sub-pixels SP may include a first sub-pixel SP1, a second sub-pixel SP2, and a third sub-pixel SP3, which emit different color light. In this case, the first sub-pixel SP1 may be a red sub-pixel, the second sub-pixel SP2 may be a green sub-pixel, and the third sub-pixel SP3 may be a blue sub-pixel, but the inventive concepts are not limited thereto.

In each of the plurality of display devices 100, each of the first sub-pixel SP1, the second sub-pixel SP2, and the third sub-pixel SP3 may be continuously disposed along the first direction. Therefore, in each of the plurality of display devices 100, only sub-pixels SP emitting the same color may be disposed in each column. Specifically, referring to FIGS. 3 and 5 together, the third sub-pixel SP3 is disposed in the first column of the display device 100, the second sub-pixel SP2 is disposed in the second column, the first sub-pixel SP1 is disposed in the third column, and the arrangement may be repeated in the subsequent column. However, the inventive concepts are not limited thereto.

The first sub-pixel SP1, the second sub-pixel SP2, and the third sub-pixel SP3 may be sequentially and repeatedly disposed along the second direction. That is, the first sub-pixel SP1, the second sub-pixel SP2, and the third sub-pixel SP3 may be alternately disposed along the second direction. Specifically, in each row of the display device 100, the first sub-pixel SP1, the second sub-pixel SP2, and the third sub-pixel SP3 may be repeatedly disposed in the order of the third sub-pixel SP3, the second sub-pixel SP2, and the first sub-pixel SP1, but are not limited thereto.

Referring to FIG. 4 together, a flexible printed circuit FPC and a printed circuit board PCB may be disposed on one side of the rear surface of the substrate.

The flexible printed circuit FPC may include a base film having flexibility and various circuit elements disposed on the base film. For example, a driving IC such as a gate driver IC or a data driver IC may be disposed on the flexible printed circuit FPC, but is not limited thereto. The driving IC may be a component that processes data for displaying an image and a driving signal. The driving IC may be distinguished according to a mounting method, and for example, may be disposed in a chip-on-film (COF) manner, but is not limited thereto.

The printed circuit board PCB is electrically connected to one or more flexible printed circuits FPC and may be a component that supplies a signal to the driving IC. The printed circuit board PCB may be disposed on one side of the flexible printed circuit FPC to be electrically connected to the flexible printed circuit FPC. Various components for supplying various signals to the driving IC may be disposed on the printed circuit board PCB. For example, various components, such as a power supply unit, a memory, or a processor, may be disposed on the printed circuit board PCB, but the inventive concepts are not limited thereto.

The display devices 100 disposed along the first direction may be disposed such that the printed circuit board PCB and the flexible printed circuit FPC of adjacent display devices 100 face each other. For example, the first display device 100a and the second display device 100b disposed in the same column may be disposed such that the printed circuit board PCB and the flexible printed circuit FPC disposed in the first display device 100a and the second display device 100b face each other. Similarly, the third display device 100c and the fourth display device 100d disposed in the same column may be disposed such that the printed circuit board PCB and the flexible printed circuit FPC disposed in the third display device 100c and the fourth display device 100d face each other.

In other words, as described above, the printed circuit board PCB and the flexible printed circuit FPC are disposed on one side of the substrate of each display device 100 so that the first display device 100a and the second display device 100b may be tiled, and one side of the substrate of the first display device 100a and one side of the substrate of the second display device 100b face each other. Likewise, the third display device 100c and the fourth display device 100d may be tiled such that one side of the substrate of the third display device 100c and one side of the substrate of the fourth display device 100d face each other.

Although not illustrated in the drawings, the tiling display device 1000 may be implemented by repeatedly arranging the display devices 100 with the same orientation. For example, in a fifth display device (not shown) that would be tiled to the first display device 100b along the first direction, the printed circuit board PCB and the flexible printed circuit FPC thereof may be formed in the upper area, similarly to the second display device 100b. In this manner, the printed circuit board PCB and the flexible printed circuit FPC of the first display device 100a and the printed circuit board PCB and the flexible printed circuit FPC of the fifth display device may not face each other.

More particularly, in the tiling display device 1000 according to an embodiment of the invention, the printed circuit boards PCB and the flexible printed circuits FPC disposed on the first display device 100a and the second display device 100b face each other, while the printed circuit boards PCB and the flexible printed circuits FPC disposed on the first display device 100a and the fifth display device do not to face each other (in opposite directions). Therefore, between some of adjacent display devices 100, the printed circuit board PCB and the flexible printed circuit FPC disposed in each of the display devices 100 may be disposed to be spaced apart as much as possible. Since the printed circuit board PCB and the flexible printed circuit FPC are distributed, heat generation of the tiling display device 1000 may be reduced.

The first display device 100a, the second display device 100b, the third display device 100c, and the fourth display device 100d have the same structure, but as described above, one side of each substrate is tiled to face each other, so in the tiled state, it may appear to have an arrangement of different pixels PX on a plane. For example, in the tiling state, the first display device 100a may be the same as the state in which the second display device 100b rotates 180° clockwise or counterclockwise, and the third display device 100c may be the same as the state in which the fourth display device 100d rotates 180° clockwise or counterclockwise.

Therefore, the plurality of first sub-pixels SP1 of the first display device 100a and the plurality of third sub-pixels SP3 of the second display device 100b may be disposed in the same column. That is, the plurality of first sub-pixels SP1 of the first display device 100a and the plurality of third sub-pixels SP3 of the second display device 100b may be continuously disposed along the first direction.

Further, the plurality of third sub-pixels SP3 of the first display device 100a and the plurality of first sub-pixels SP1 of the second display device 100b may be disposed in the same column. That is, the plurality of third sub-pixels SP3 of the first display device 100a and the plurality of first sub-pixels SP1 of the second display device 100b may be continuously disposed along the first direction.

Likewise, the plurality of first sub-pixels SP1 of the third display device 100c and the plurality of third sub-pixels SP3 of the fourth display device 100d may be disposed in the same column. That is, the plurality of first sub-pixels SP1 of the third display device 100c and the plurality of third sub-pixels SP3 of the fourth display device 100d may be continuously disposed along the first direction.

Further, the plurality of third sub-pixels SP3 of the third display device 100c and the plurality of first sub-pixels SP1 of the fourth display device 100d may be disposed in the same column. That is, the plurality of third sub-pixels SP3 of the third display device 100c and the plurality of first sub-pixels SP1 of the fourth display device 100d may be continuously disposed along the first direction.

Accordingly, the plurality of first sub-pixels SP1 of the first display device 100a may be alternately disposed with the plurality of first sub-pixels SP1 of the second display device 100b, and the plurality of third sub-pixels SP3 of the first display device 100a may be alternately disposed with the plurality of third sub-pixels SP3 of the second display device 100b.

Likewise, the plurality of first sub-pixels SP1 of the third display device 100c may be alternately disposed with the plurality of first sub-pixels SP1 of the fourth display device 100d, and the plurality of third sub-pixels SP3 of the third display device 100c may be alternately disposed with the plurality of third sub-pixels SP3 of the fourth display device 100d.

The second sub-pixel SP2 is disposed in the middle of the first sub-pixel SP1, the second sub-pixel SP2, and the third sub-pixel SP3 so that the second sub-pixel SP2 may be disposed in the same column as the second sub-pixel SP2 of the display device 100 adjacent in the first direction. That is, the plurality of second sub-pixels SP2 of the first display device 100a and the plurality of second sub-pixels SP2 of the second display device 100b may be continuously disposed along the first direction.

Likewise, the plurality of second sub-pixels SP2 of the third display device 100c and the plurality of second sub-pixels SP2 of the fourth display device 100d may be continuously disposed along the first direction.

According to an embodiment, not only the arrangement of components of each of the plurality of display devices 100, but also the driving method may be the same. For example, a plurality of scan signals supplied from the gate driver GD may be supplied in the same direction and order from each of the plurality of display devices 100. For example, referring to FIG. 5, the gate driver GD may be configured to transmit a scan signal from a sub-pixel SP disposed on the other side of the substrate, which is opposite to one side of the substrate on which the printed circuit board PCB and the flexible printed circuit FPC are disposed, among the plurality of sub-pixels SP, to the sub-pixel SP disposed on one side of the substrate.

For example, in each of the plurality of display devices 100, when the plurality of sub-pixels SP is arranged in m rows and n columns, a row closest to the printed circuit board PCB and the flexible printed circuit FPC is referred to as a first row and a row farthest from the first row is referred to as an “m-th row”. Here, “m” and “n” are natural numbers of 2 or more.

That is, with reference to FIG. 3, as in the second display device 100b and the fourth display device 100d, when the printed circuit board PCB and the flexible printed circuit FPC are disposed in the upper region of the display device 100 in a tiled state of the plurality of display devices 100, the sub-pixel SP disposed in the upper left corner is the sub-pixel SP of the first row and the first column, and the sub-pixel SP disposed in the lower right corner is the sub-pixel SP of the m-th row and the n-th column.

Similarly, like the first display device 100a and the third display device 100c, when the printed circuit board PCB and the flexible printed circuit FPC are disposed in a lower area of the display device 100 in a tiled state of the plurality of display devices 100, a sub-pixel SP disposed at the upper left corner may be a sub-pixel SP of the m-th row and the n-th column, and a sub-pixel SP disposed at the lower right corner may be a sub-pixel SP of the first row and the first column.

That is, in each display device 100, the sub-pixels SP disposed in the first row among the plurality of sub-pixels SP may be disposed to face the sub-pixels SP disposed in the first row of the display device 100 adjacent in the first direction. For example, the sub-pixel SP disposed in the first row of the first display device 100a may be disposed to face the sub-pixel SP disposed in the first row of the second display device 100b. Similarly, the sub-pixel SP disposed in the first row of the third display device 100c may be disposed to face the sub-pixel SP disposed in the first row of the fourth display device 100d, but is not limited thereto.

Referring back to FIG. 5 together, in each of the display devices 100, a scan signal of the gate driver GD may be applied in sequence from a sub-pixel SP disposed in the m-th row to a sub-pixel SP disposed in the first row. That is, as described above, by making the driving methods of the plurality of display devices 100 constituting the tiling display device 1000 the same as each other, it is possible to minimize the deviation of the driving timing, luminance, and color temperature between the display devices 100.

A tiling display device having a large screen may be implemented by connecting a plurality of display devices. In this case, in order to improve the display quality, a driving deviation between the display device and the display device must be minimized. Here, the driving deviation includes not only the deviation of the driving timing but also the deviation of the display quality such as luminance, color temperature, and color coordinates, and in order to express a smooth image, it is important to minimize the driving deviation between the display devices.

Compensation, such as luminance and color temperature, for the tiling display device may be performed based on a predetermined driving method. In this case, when the driving methods between the display devices constituting the tiling display device are different from each other, the above-described driving deviation may occur when a display device is driven by a driving method different from the driving method that serves as a reference for compensation.

Accordingly, in the tiling display device 1000 according to an exemplary embodiment of the invention, a driving method of a plurality of display devices 100 constituting the tiling display device 1000, that is, the first display device 100a, the second display device 100b, the third display device 100c, and the fourth display device 100d may be the same. For example, a plurality of scan signals supplied from the gate driver GD may be supplied in the same direction and order in each display device 100. Specifically, the scan signal of the gate driver GD may be transmitted from the sub-pixel SP disposed on the other side of the substrate, which is opposite to one side of the substrate on which the printed circuit board PCB and the flexible printed circuit FPC are disposed, among the plurality of sub-pixels SP, to the sub-pixel SP disposed on one side of the substrate. That is, the tiling display device 1000 according to an embodiment of the invention unifies a driving method between a plurality of display devices 100 to perform driving compensation for each display device 100 according to the same criterion. Accordingly, it is possible to minimize a deviation in display quality between the display devices 100. Accordingly, the display quality of the tiling display device 1000 may be improved.

In the tiling display device 1000 according to an embodiment of the invention, the display device 100 disposed along the first direction may be disposed such that the printed circuit board PCB and the flexible printed circuit FPC face each other. For example, the first display device 100a and the second display device 100b disposed in the same column may be disposed such that the printed circuit board PCB and the flexible printed circuit FPC disposed in each of the first display device 100a and the second display device 100b face each other. Similarly, the third display device 100c and the fourth display device 100d disposed in the same column may be disposed such that the printed circuit board PCB and the flexible printed circuit FPC disposed in each of the third display device 100c and the fourth display device 100d face each other. The display device 100 is repeatedly arranged so that the tiling display device 1000 according to an embodiment of the invention may be implemented. That is, a structure in which one side of the substrate on which the printed circuit board PCB and the flexible printed circuit FPC are disposed faces each other, which is the opposite side of one side, faces each other may be repeatedly arranged. In other words, in the tiling display device 1000 according to an embodiment of the invention, the printed circuit board PCB and the flexible printed circuit FPC of adjacent display devices 100 may not only be disposed to face each other, like the first display device 100a and the second display device 100b, but also may be disposed to face opposite directions. Therefore, between some of the display devices 100, the printed circuit board PCB and the flexible printed circuit FPC disposed in each of the display devices 100 may be disposed to be spaced apart as much as possible. That is, since the printed circuit board PCB and the flexible printed circuit FPC are distributed, heat generation of the tiling display device 1000 may be reduced. Accordingly, potential defects of the tiling display device 1000 due to heat generation are minimized, thereby improving the life of the tiling display device 1000.

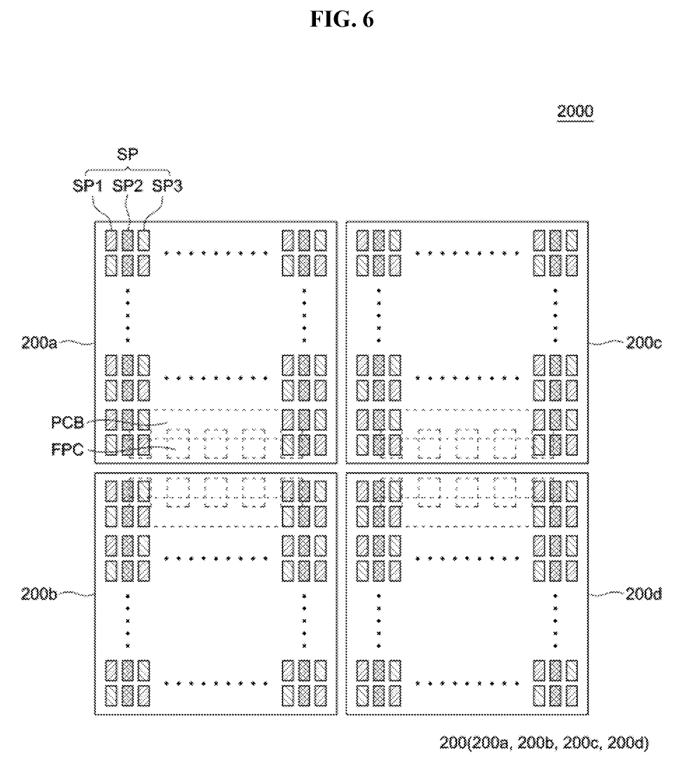

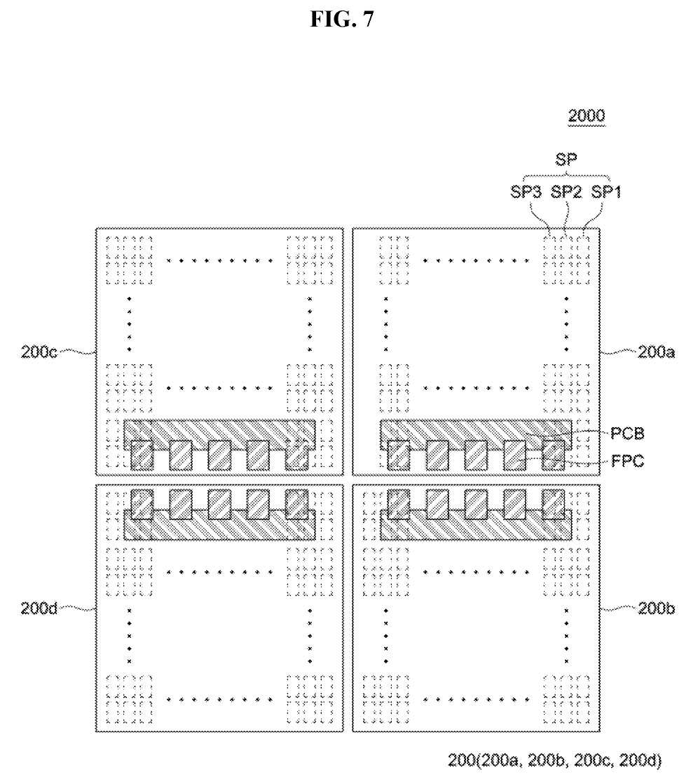

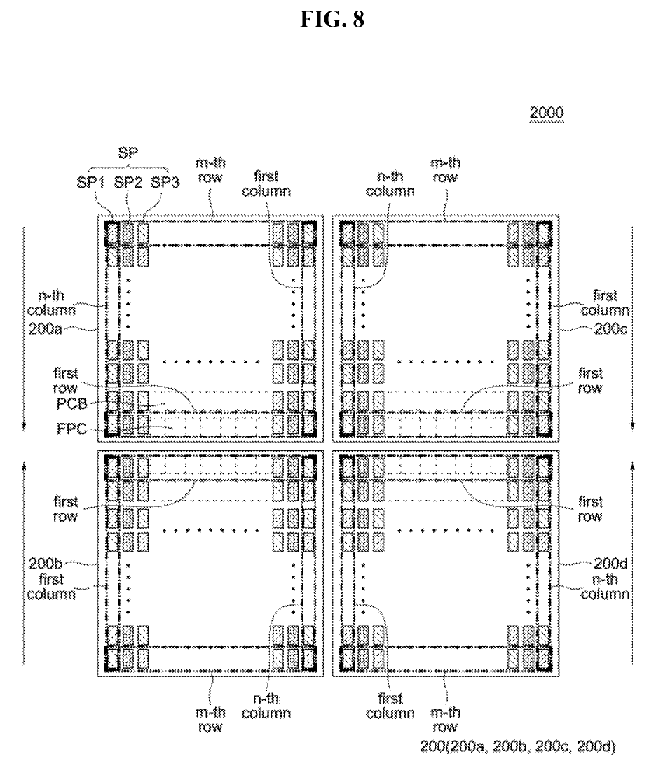

FIG. 6 is a plan view of a tiling display device according to another embodiment of the invention. FIG. 7 is a rear plan view of a tiling display device according to another embodiment of the invention. FIG. 8 is a diagram for explaining an order of applying a scan signal to a tiling display device according to another embodiment of the invention. An arrow in FIG. 8 indicates a scan signal application direction. A tiling display device 2000 of FIGS. 6 to 8 is substantially identical in configuration to the tiling display device 1000 of FIGS. 1 to 5, except for a subpixel SP arrangement structure of a plurality of display devices 200. Therefore, repeated descriptions of the identical components will be omitted.

Referring to FIGS. 6 to 8, the plurality of display devices 200 may include a first display device 200a, a second display device 200b, a third display device 200c, and a fourth display device 200d having the same arrangement structure as the sub-pixel SP. For example, the first display device 200a may be disposed in the same column as the second display device 200b, and the third display device 200c may be disposed in the same column as the fourth display device 200d. The first display device 200a may be disposed on the same row as the third display device 200c, and the second display device 200b may be disposed on the same row as the fourth display device 200d. As described above, the first display device 200a, the second display device 200b, the third display device 200c, and the fourth display device 200d are repeatedly arranged to implement the tiling display device 2000. However, the invention is not limited thereto.

In each of the plurality of display devices 200, the first sub-pixel SP1 and the third sub-pixel SP3 may be alternately disposed along the first direction, and the second sub-pixel SP2 may be continuously disposed along the first direction. Therefore, only the second sub-pixel SP2 may be disposed in some columns, and the first sub-pixel SP1 and the third sub-pixel SP3 may be alternately disposed in the remaining columns. Specifically, the first sub-pixel SP1 and the third sub-pixel SP3 are alternately disposed in the first column of the display device 200, only the second sub-pixel SP2 is disposed in the second column, and such an arrangement may be repeated in the subsequent column, but the inventive concepts are not limited thereto.

The first sub-pixel SP1, the second sub-pixel SP2, and the third sub-pixel SP3 may be sequentially and repeatedly disposed along the second direction. That is, the first sub-pixel SP1, the second sub-pixel SP2, and the third sub-pixel SP3 may be alternately disposed along the second direction. Specifically, in the first row of the display device 200, the first sub-pixel SP1, the second sub-pixel SP2, and the third sub-pixel SP3 may be repeatedly disposed along the second direction in the order of the first sub-pixel SP1, the second sub-pixel SP2, and the third sub-pixel SP3. In the second row, the third sub-pixel SP3, the second sub-pixel SP2, and the first sub-pixel SP1 may be repeatedly disposed along the first direction in the order of the third sub-pixel SP3, the second sub-pixel SP2, and the first sub-pixel SP1. Such an arrangement may be repeated in a subsequent row, but the inventive concepts are not limited thereto.

Because the printed circuit board PCB and the flexible printed circuit FPC are disposed on one side of the substrate of each display device 200, the first display device 200a and the second display device 200b may be tiled such that one side of the substrate of the first display device 200a and one side of the second display device 200b face each other. Similarly, the third display device 200c and the fourth display device 200d may be tiled such that one side of the substrate of the third display device 200c and one side of the substrate of the fourth display device 200d face each other.

Although not illustrated in the drawings, the tiling display device 2000 may be implemented by repeatedly arranged the display devices 200 with the same orientation. For example, in a fifth display device (not shown) that would be tiled to the first display device 200a along the first direction, the printed circuit board PCB and the flexible printed circuit FPC may be formed in the upper area, similarly to the second display device 200b. In this manner, the printed circuit board PCB and the flexible printed circuit FPC of the first display device 200a and the printed circuit board PCB and the flexible printed circuit FPC of the fifth display device may not face each other.

That is, in the tiling display device 2000 according to another embodiment of the invention, the printed circuit board PCB and the flexible printed circuit FPC disposed on each of the first display device 200a and the second display device 200b are disposed to face each other, while the printed circuit boards PCB and the flexible printed circuits FPC disposed on some of adjacent display devices 200 may not to face each other (opposite directions). Therefore, between some of adjacent display devices 200, the printed circuit board PCB and the flexible printed circuit FPC disposed in each of the display devices 200 may be disposed to be spaced apart as much as possible. Since the printed circuit board PCB and the flexible printed circuit FPC are distributed, heat generation of the tiling display device 2000 may be reduced.

The first display device 200a, the second display device 200b, the third display device 200c, and the fourth display device 200d have the same structure, but as described above, one side of each substrate is tiled to face each other, so in the tiled state, it may appear to have different pixel PX arrangements on a plane. For example, in the tiling state, the first display device 200a may be the same as the state in which the second display device 200b rotates 180° clockwise or counterclockwise, and the third display device 200c may be the same as the state in which the fourth display device 200d rotates 180° clockwise or counterclockwise.

Therefore, the plurality of first sub-pixels SP1 and the plurality of third sub-pixels SP3 may be alternately disposed along the first direction in the first display device 200a and the second display device 200b.

Accordingly, the plurality of first sub-pixels SP1 of the first display device 200a may be disposed in the same column as the plurality of first sub-pixels SP1 as well as the plurality of third sub-pixels SP3 of the second display device 200b.

For example, in the tiling state, when the plurality of first sub-pixels SP1 of the first display device 200a and the plurality of first sub-pixels SP1 of the second display device 200b are alternately disposed in different columns, there may be a problem in that the display quality is deteriorated, such as an image is not smoothly displayed in a specific pixel driving pattern. Further, in the pixel arrangement structure, lines connected to the first sub-pixels SP1 of each display device 200 are also alternately disposed in the first display device 200a and the second display device 200b, so that the difficulty of the process may increase in that the display device must be tiled in consideration of such a line structure.

On the other hand, in the tiling display device 2000 according to another embodiment of the invention, since the plurality of first sub-pixels SP1 of the first display device 200a and the plurality of first sub-pixels SP1 of the second display device 200b are disposed in the same column, the display quality may be improved compared to the above-described pixel arrangement structure, and the line connected to the plurality of first sub-pixels SP1 is not disposed alternately in the first display device 200a and the second display device 200b, which may minimize the complexity of the tiling design.

Further, the plurality of third sub-pixels SP3 of the first display device 200a may be disposed in the same column as the plurality of third sub-pixels SP3 as well as the plurality of first sub-pixels SP1 of the second display device 200b. Therefore, as described above, the display quality of the tiling display device 2000 may be improved, and lines connected to the plurality of third sub-pixels SP3 are not alternately disposed in the first display device 200a and the second display device 200b, which may minimize the complexity of the tiling design. Likewise, the plurality of first sub-pixels SP1 and the plurality of third sub-pixels SP3 may be alternately disposed along the first direction in the third display device 200c and the fourth display device 200d.

Accordingly, the plurality of first sub-pixels SP1 of the third display device 200c may be disposed in the same column as the plurality of first sub-pixels SP1 as well as the plurality of third sub-pixels SP3 of the fourth display device 200d. Therefore, as described above, the display quality of the tiling display device 2000 may be improved, and lines connected to the plurality of first sub-pixels SP1 are not alternately disposed in the third display device 200c and the fourth display device 200d, which may minimize the complexity of the tiling design.

Further, the plurality of third sub-pixels SP3 of the third display device 200c may be disposed in the same column as the plurality of third sub-pixels SP3 as well as the plurality of first sub-pixels SP1 of the fourth display device 200d. Therefore, as described above, the display quality of the tiling display device 2000 may be improved, and lines connected to the plurality of third sub-pixels SP3 are not alternately disposed in the third display device 200c and the fourth display device 200d, which may minimize the complexity of the tiling design.

Not only the arrangement of components of each of the plurality of display devices 200, but also the driving method may be the same. For example, a plurality of scan signals supplied from the gate driver GD may be supplied in the same direction and order in each of the plurality of display devices 200. For example, referring to FIG. 8, the gate driver GD may be configured to transmit a scan signal from a sub-pixel SP disposed on the other side of the substrate, which is opposite to one side of the substrate on which the printed circuit board PCB and the flexible printed circuit FPC are disposed, among the plurality of sub-pixels SP, to the sub-pixel SP disposed on one side of the substrate.

That is, in each of the plurality of display devices 200, the scan signal of the gate driver GD may be transmitted from the sub-pixel SP disposed in the row m to the sub-pixel SP disposed in the first row. In this way, by making the driving methods of the plurality of display devices 200 constituting the tiling display device 2000 the same, it is possible to minimize variations in driving timing, luminance, and color temperature between the display devices 200.

In the tiling display device 2000 according to another embodiment of the invention, a driving method of a plurality of display devices 200 constituting the tiling display device 2000 that is, the first display device 200a, the second display device 200b, the third display device 200c, and the fourth display device 200d may be the same. For example, a plurality of scan signals supplied from the gate driver GD may be supplied in each display device 200 in the same direction and the same order. Specifically, the scan signal of the gate driver GD may be transmitted from the sub-pixel SP disposed on the other side of the substrate, which is opposite to one side of the substrate on which the printed circuit board PCB and the flexible printed circuit FPC are disposed, among the plurality of sub-pixels SP, to the sub-pixel SP disposed on one side of the substrate. That is, the tiling display device 2000 according to another embodiment of the invention unifies the driving method between the plurality of display devices 200, so that driving compensation for each display device 200 may be performed according to the same reference. Accordingly, it is possible to minimize a deviation in display quality between the display devices 200. Accordingly, the display quality of the tiling display device 2000 may be improved.

In the tiling display device 2000 according to another embodiment of the invention, the display device 200 disposed along the first direction may be disposed such that the printed circuit board PCB and the flexible printed circuit FPC face each other. For example, the first display device 200a and the second display device 200b disposed in the same column may be disposed such that the printed circuit board PCB and the flexible printed circuit FPC disposed in each of the first display device 200a and the second display device 200b face each other. Similarly, the third display device 200c and the fourth display device 200d disposed in the same column may be disposed such that the printed circuit board PCB and the flexible printed circuit FPC disposed in each of the third display device 200c and the fourth display device 200d face each other. The arrangement structure of the display device 200 is repeated so that the tiling display device 2000 according to another embodiment of the invention may be implemented. That is, a structure in which one side of the substrate on which the printed circuit board PCB and the flexible printed circuit FPC are disposed faces each other and the other side, which is the opposite side of one side, faces each other may be repeated. In other words, in the tiling display device 2000 according to another embodiment of the invention, like the first display device 200a and the second display device 200b, the printed circuit board PCB and the flexible printed circuit FPC disposed on each other may be disposed to face each other, and the printed circuit board PCB and the flexible printed circuit FPC disposed on each of the display devices 200 may be disposed not to face each other (opposite directions) (not shown). Therefore, between some of the display devices 200, the printed circuit board PCB and the flexible printed circuit FPC disposed in each of the display devices 200 may be disposed to be spaced apart as much as possible. That is, since the printed circuit board PCB and the flexible printed circuit FPC are distributed, heat generation of the tiling display device 2000 may be reduced. Accordingly, potential defects of the tiling display device 2000 due to heat generation are minimized, thereby improving the life of the tiling display device 2000.

In particular, in each display device 200 constituting the tiling display device 2000 according to another embodiment of the invention, the first sub-pixel SP1 and the third sub-pixel SP3 may be alternately disposed along the first direction. Therefore, the plurality of first sub-pixels SP1 of the first display device 200a may be disposed in the same column as the plurality of first sub-pixels SP1 of the second display device 200b adjacent to the first display device 200a in the first direction. Further, the plurality of third sub-pixels SP3 of the first display device 200a may be disposed in the same column as the plurality of third sub-pixels SP3 of the second display device 200b. Likewise, the plurality of first sub-pixels SP1 of the third display device 200c may be disposed in the same column as the plurality of first sub-pixels SP1 of the fourth display device 200d adjacent to the third display device 200c in the first direction. Further, the plurality of third sub-pixels SP3 of the third display device 200c may be disposed in the same column as the plurality of third sub-pixels SP3 of the fourth display device 200d. That is, the first sub-pixel SP1 may be disposed in the same column as the first sub-pixel of the plurality of display devices 200 disposed along the first direction, and the third sub-pixel SP3 may be disposed in the same column as the third sub-pixel SP3 of the plurality of display devices 200 disposed along the first direction. Therefore, as compared with the case where the first sub-pixels SP1 disposed in the display device 200 adjacent in the first direction in the tiling state are alternately disposed in different columns, it is possible to minimize a problem in which the display quality deteriorates, such as the image is not smoothly displayed in the specific pixel PX driving pattern. Further, in the tiling display device 2000 according to another embodiment of the invention, lines connected to the plurality of first sub-pixels SP1 are not alternately disposed in the display device 200 adjacent to each other in the first direction. Therefore, it is possible to minimize the complexity of the tiling design.

According to embodiments of the invention, by unifying a driving method between a plurality of display devices constituting a tiling display device, it is possible to minimize a driving deviation between the plurality of display devices.

According to embodiments of the invention, it is possible to minimize a deviation in display quality between a plurality of display devices constituting a tiling display device so that the tiling display device uniformly displays an image.

According to embodiments of the invention, the display quality of the tiling display device may be improved.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A tiling display device including a plurality of display devices, wherein:
the plurality of display devices include a first display device and a second display device, each including:
a substrate including an active area in which a plurality of sub-pixels is defined and a non-active area surrounding the active area;
a plurality of light emitting elements disposed in each of the plurality of sub-pixels on the substrate;
a printed circuit board disposed on one side of the substrate on a rear surface of the substrate and electrically connected to the plurality of light emitting elements; and
a gate driver configured to transmit a scan signal to the plurality of sub-pixels; and
at least one of the gate drivers is configured to transmit the scan signal from a sub-pixel disposed on the other side opposite to the one side of the substrate, among the plurality of sub-pixels, to a sub-pixel disposed on the one side of the substrate.

2. The tiling display device according to claim 1, wherein the first display device and the second display device are tiled so that the one side of the substrate of the first display device and the one side of the second display device face each other.

3. The tiling display device according to claim 2, wherein:
the plurality of sub-pixels include a plurality of first sub-pixels, a plurality of second sub-pixels, and a plurality of third sub-pixels configured to emit light of different colors;
the plurality of first sub-pixels, the plurality of second sub-pixels, and the plurality of third sub-pixels are respectively continuously disposed along a first direction; and
the plurality of first sub-pixels, the plurality of second sub-pixels, and the plurality of third sub-pixels are alternately disposed along a second direction.

4. The tiling display device according to claim 3, wherein, in a state in which the first display device and the second display device are tiled:
the plurality of first sub-pixels of the first display device and the plurality of third sub-pixels of the second display device are continuously disposed along the first direction; and
the plurality of third sub-pixels of the first display device and the plurality of first sub-pixels of the second display device are continuously disposed along the first direction.

5. The tiling display device according to claim 3, wherein, in a state in which the first display device and the second display device are tiled:
the plurality of first sub-pixels of the first display device are alternately disposed with the plurality of first sub-pixels of the second display device; and
the plurality of third sub-pixels of the first display device are alternately disposed with the plurality of third sub-pixels of the second display device.

6. The tiling display device according to claim 3, wherein, in a state in which the first display device and the second display device are tiled, the plurality of second sub-pixels of the first display device and the plurality of second sub-pixels of the second display device are continuously disposed along the first direction.

7. The tiling display device according to claim 2, wherein:
the plurality of sub-pixels include a plurality of first sub-pixels, a plurality of second sub-pixels, and a plurality of third sub-pixels configured to emit light of different colors; and
the plurality of first sub-pixels and the plurality of third sub-pixels are alternately disposed along a first direction, the plurality of second sub-pixels are continuously disposed along the first direction, and the plurality of first sub-pixels, the plurality of second sub-pixels, and the plurality of third sub-pixels are alternately disposed along a second direction.

8. The tiling display device according to claim 7, wherein, in a state in which the first display device and the second display device are tiled, the plurality of first sub-pixels and the plurality of third sub-pixels are alternately disposed along the first direction in the first display device and the second display device.

9. The tiling display device according to claim 7, wherein, in a state in which the first display device and the second display device are tiled, the plurality of second sub-pixels of the first display device and the plurality of second sub-pixels of the second display device are continuously disposed along the first direction.

10. A tiling display device in which a plurality of display devices are tiled, wherein:
each of the plurality of display devices includes:
a substrate including an active area and a non-active area surrounding the active area;
a plurality of sub-pixels disposed on the substrate along first to m-th rows and first to n-th columns (where m and n are natural numbers of 2 or more);
a plurality of light emitting elements disposed in each of the plurality of sub-pixels; and
a printed circuit board disposed on one side of the substrate along a row direction on a rear surface of the substrate and electrically connected to the plurality of light emitting elements;
the printed circuit board is disposed to be adjacent to the sub-pixels disposed in the first row among the first row to the m-th row; and
a sub-pixel disposed in the first row among the plurality of sub-pixels is disposed to face a sub-pixel disposed in the first row of the plurality of display devices adjacent in a column direction.

11. The tiling display device according to claim 10, wherein:
each of the plurality of display devices further includes a gate driver configured to transmit a scan signal to the plurality of sub-pixels; and
at least one of the gate drivers is configured to transmit the scan signal from a sub-pixel disposed in the m-th row to a sub-pixel disposed in the first row among the plurality of sub-pixels.

12. The tiling display device according to claim 10, wherein the plurality of display devices adjacent to each other in the column direction are disposed so that the printed circuit boards disposed in each of the plurality of display devices face each other.

13. The tiling display device according to claim 12, wherein:
the plurality of sub-pixels includes a plurality of first sub-pixels, a plurality of second sub-pixels, and a plurality of third sub-pixels configured to emit light of different colors; and
in each of the plurality of display devices:
the plurality of first sub-pixels, the plurality of second sub-pixels, and the plurality of third sub-pixels are respectively continuously disposed along the column direction; and
the plurality of first sub-pixels, the plurality of second sub-pixels, and the plurality of third sub-pixels are alternately disposed along the row direction.

14. The tiling display device according to claim 13, wherein:
the plurality of first sub-pixels of the plurality of display devices are disposed in a same column as the plurality of third sub-pixels of the display device adjacent to the plurality of display devices in the column direction; and
the plurality of third sub-pixels of the plurality of display devices are disposed in a same column as the plurality of first sub-pixels of the display device adjacent to the plurality of display devices in the column direction.

15. The tiling display device according to claim 13, wherein the plurality of second sub-pixels of the plurality of display devices are disposed in the same column as the plurality of second sub-pixels of the display device adjacent to the plurality of display devices in the column direction.

16. The tiling display device according to claim 12, wherein:
the plurality of sub-pixels includes a plurality of first sub-pixels, a plurality of second sub-pixels, and a plurality of third sub-pixels configured to emit light of different colors; and
in each of the plurality of display devices:
the plurality of first sub-pixels and the plurality of third sub-pixels are alternately disposed along the column direction;
the plurality of second sub-pixels are continuously disposed along the column direction, and
the plurality of first sub-pixels, the plurality of second sub-pixels, and the plurality of third sub-pixels are alternately disposed along the row direction.

17. The tiling display device according to claim 16, wherein:
the plurality of first sub-pixels of the plurality of display devices are disposed in the same column as the plurality of first sub-pixels of the display device adjacent to the plurality of display devices in the column direction; and
the plurality of third sub-pixels of the plurality of display devices are disposed in the same column as the plurality of third sub-pixels of the display device adjacent to the plurality of display devices in the column direction.

18. The tiling display device according to claim 16, wherein the plurality of second sub-pixels of the plurality of display devices are disposed in the same column as the plurality of second sub-pixels of the display device adjacent to the plurality of display devices in the column direction.

19. A tiling display device comprising a first display device and a second display device arranged adjacent to each other in a first direction, wherein:
one side of the first display device faces one side of the second display device; and
each of the first display device and the second display device comprises:
a substrate including an active area in which a plurality of sub-pixels is defined and a non-active area surrounding the active area;
a plurality of light emitting elements respectively disposed in the plurality of sub-pixels;
a printed circuit board disposed on a rear surface of the substrate at the one side of the substrate and electrically connected to the plurality of light emitting elements; and
a gate driver configured to apply a scan signal to the plurality of sub-pixels by row from the other side opposite to the one side toward the one side.
